(19) United States
(12) Patent Application Publication
(10) Pub. No.: US 2014/0124837 A1
(43) Pub. Date: May 8, 2014

(54) NITRIDE SEMICONDUCTOR DEVICE AND METHOD FOR MANUFACTURING SAME

(71) Applicants: Norihisa Fujii, Osaka-shi (JP); Koichiro Fujita, Osaka-shi (JP)

(72) Inventors: Norihisa Fujii, Osaka-shi (JP); Koichiro Fujita, Osaka-shi (JP)

(73) Assignee: SHARP KABUSHIKI KAISHA, Osaka-shi, Osaka (JP)

(21) Appl. No.: 14/125,765

(22) PCT Filed: Aug. 8, 2012
(86) PCT No.: PCT/JP2012/070156

§ 371 Date: Dec. 12, 2013

(30) Foreign Application Priority Data
Sep. 27, 2011 (JP) 2011-211286

(51) Int. Cl. H01L 29/778; H01L 21/02; H01L 29/66; H01L 29/205

(52) U.S. Cl. CPC H01L 29/7786; H01L 29/205; H01L 21/0254; H01L 29/66431
USPC 257/194; 438/172

(57) ABSTRACT

A nitride semiconductor device includes an undoped GaN layer (1) and an undoped AlGaN layer (2) that are formed on an Si substrate (10), and ohmic electrodes (a source electrode (11) and a drain electrode (12)) that are formed on the undoped GaN layer (1) and the undoped AlGaN layer (2) and that are made of Ti/Al/TiN. Concentration of nitrogen in the ohmic electrodes is set in a range from 1×10¹⁶ cm⁻³ to 1×10²⁰ cm⁻³. Consequently, contact resistance between the nitride semiconductor layers and the ohmic electrodes can be reduced.

### TECHNICAL FIELD

The present invention relates to nitride semiconductor devices and methods for manufacturing the same.

### BACKGROUND ART

There has been a conventional nitride semiconductor device in which two-dimensional electron gas is formed in a GaN layer adjacent to an interface between the GaN layer and an AlGaN layer (see JP 2007-158149 A (PTL 1), for instance). In the nitride semiconductor device, metal is deposited by sputtering in recessed parts formed by removal of portions of the AlGaN layer and the GaN layer, so that a source electrode and a drain electrode which are in contact with the two-dimensional electron gas are formed as ohmic electrodes. Then heat treatment of the source electrode and the drain electrode at a high temperature of 800° C. provides ohmic contact between the two-dimensional electron gas and the source and drain electrodes.

When the inventor actually and experimentally formed the ohmic electrodes by the heat treatment at the high temperature of 800° C. for the nitride semiconductor device, however, the ohmic electrodes had high contact resistances and sufficiently low contact resistances could not be obtained.

### CITATION LIST

### Patent Literature

PTL1: JP 2007-158149 A

### SUMMARY OF INVENTION

### Technical Problem

It is an object of the invention to provide a nitride semiconductor device in which contact resistances between a nitride semiconductor layer and ohmic electrodes can be reduced and a method for manufacturing the same.

### Solution to Problem

The inventor diligently examined contact resistance of ohmic electrodes formed on nitride semiconductor layers, without doping of a GaN layer with nitrogen as in the conventional nitride semiconductor device, and consequently found that characteristic of the contact resistance between the nitride semiconductor layers and the ohmic electrodes changes according to concentration of nitrogen in the ohmic electrodes, when such an amount of nitrogen atoms as not forming nitride are included as impurities in the ohmic electrodes made of TiAl-based material.

The invention is based on such a finding of the inventor and an initial finding from experiments that the contact resistance greatly decreases on condition that the concentration of nitrogen in the ohmic electrodes is within a specific range.

That is, a nitride semiconductor device in accordance with a first invention comprises:

a substrate,

a nitride semiconductor layer formed on the substrate, and

ohmic electrodes formed on the nitride semiconductor layer and made of TiAl-based material, wherein

concentration of nitrogen in the ohmic electrodes made of the TiAl-based material is in a range from 1×10¹⁶ cm⁻³ to 1×10²⁰ cm⁻³.

Nitride semiconductor of the nitride semiconductor device has only to be a material that can be expressed as AlₓIn_{y}Ga_{1-x-y}N (x≧0, y≧0, 0≦x+y≦1). The TiAl-based material includes at least Ti/Al and a TiN cap layer may be laminated thereon or Au, Ag, Pt and/or the like may be laminated on the Al.

With above configuration, the contact resistance between the nitride semiconductor layers and the ohmic electrodes can be reduced by setting of the concentration of nitrogen in the ohmic electrodes made of the TiAl-based material in the range from 1×10¹⁶ cm⁻³ to 1×10²⁰ cm⁻³.

In a nitride semiconductor device in accordance with an embodiment,

the nitride semiconductor layers comprise a first semiconductor layer and a second semiconductor layer forming a hetero interface in conjunction with the first semiconductor layer, the first and second semiconductor layers laminated on the substrate in order of mention, wherein

two-dimensional electron gas is formed in the hetero interface between the first semiconductor layer and the second semiconductor layer, wherein

recessed parts are formed in portions of upper side of the first semiconductor layer so as to extend through the second semiconductor layer, and wherein at least parts of the ohmic electrodes are embedded in the recessed parts.

In the embodiment, the contact resistance between the two-dimensional electron gas in the hetero interface between the first semiconductor layer and the second semiconductor layer and the ohmic electrodes can be reduced in the nitride semiconductor device having a recess structure in which at least the parts of the ohmic electrodes are embedded in the recessed parts that are formed in the portions of the upper side of the first semiconductor layer so as to extend through the second semiconductor layer.

In a nitride semiconductor device in accordance with an embodiment,

the ohmic electrodes made of the TiAl-based material are laminated metal films having at least a Ti layer and an Al layer laminated from a side of the substrate in order of mention.

In the embodiment, the concentration of nitrogen in the ohmic electrodes can easily be controlled so as to be in the range from 1×10¹⁶ cm⁻³ to 1×10²⁰ cm⁻³ with use of the ohmic electrodes that are the laminated metal films having at least the Ti layer and the Al layer laminated on the substrate in order of mention and by a step of including nitrogen in the Ti layer in production thereof.

A method for manufacturing a nitride semiconductor device in accordance with a second invention comprises steps of:

forming nitride semiconductor layers on a substrate,

forming a metal film made of TiAl-based material on the nitride semiconductor layers by sputtering,

forming ohmic electrodes by etching the metal film made of the TiAl-based material, and

annealing the substrate having the ohmic electrodes formed thereon, wherein

concentration of nitrogen in the ohmic electrodes is controlled so as to be in a range from 1×10¹⁶ cm⁻³ to 1×10²⁰ cm⁻³ by flow of nitrogen in a chamber during the sputtering of a Ti layer in the metal film made of the

TiAl-based material in the step of forming the metal film made of the TiAl-based material.

With above configuration, the contact resistance between the nitride semiconductor layers and the ohmic electrodes can be reduced by control of the concentration of nitrogen in the ohmic electrodes into the range from 1×10¹⁶ cm⁻³ to 1×10²⁰ cm⁻³ by the flow of nitrogen in the chamber during the sputtering of the Ti layer in the metal film made of the TiAl-based material in the step of forming the metal film made of the TiAl-based material.

A method for manufacturing a nitride semiconductor device in accordance with a third invention comprises steps of:

forming nitride semiconductor layers on a substrate,

forming a metal film made of TiAl-based material on the nitride semiconductor layers by sputtering,

forming ohmic electrodes by etching the metal film made of the TiAl-based material, and

annealing the substrate having the ohmic electrodes formed thereon, wherein

concentration of nitrogen in the ohmic electrodes is controlled so as to be in a range from 1×10¹⁶ cm⁻³ to 1×10²⁰ cm⁻³ by flow of nitrogen in a chamber before the sputtering of a Ti layer in the metal film made of the TiAl-based material in the step of forming the metal film made of the TiAl-based material.

With above configuration, the contact resistance between the nitride semiconductor layers and the ohmic electrodes can be reduced by control of the concentration of nitrogen in the ohmic electrodes into the range from 1×10¹⁶ cm⁻³ to 1×10²⁰ cm⁻³ by the flow of nitrogen in the chamber before the sputtering of the Ti layer in the metal film made of the TiAl-based material in the step of forming the metal film made of the TiAl-based material.

In an embodiment of the method for manufacturing the nitride semiconductor device in accordance with the second and third invention,

the nitride semiconductor layer is formed by laminating a first semiconductor layer and a second semiconductor layer forming a hetero interface in conjunction with the first semiconductor layer, on the substrate in order of mention, and the method further comprising a step of:

forming recessed parts extending through the second semiconductor layer into portions of upper side of the first semiconductor layer, by etching, after forming the nitride semiconductor layers and before forming the metal film made of the TiAl-based material by the sputtering, wherein

the ohmic electrodes having at least parts thereof embedded in the recessed parts are formed by the etching of the metal film made of the TiAl-based material in the step of forming the ohmic electrodes.

In the embodiment, the contact resistance between two-dimensional electron gas in the hetero interface between the first semiconductor layer and the second semiconductor layer and the ohmic electrodes can be reduced in the nitride semiconductor device having the recess structure in which at least the parts of the ohmic electrodes are embedded in the recessed parts that are formed by the etching in the portions of the upper side of the first semiconductor layer so as to extend through the second semiconductor layer.

In a method for manufacturing a nitride semiconductor device in accordance with an embodiment,

the substrate having the ohmic electrodes formed thereon is heated at a temperature in a range from 400° C. to 500° C. in the annealing step.

In the embodiment, the substrate having the ohmic electrodes formed thereon is heated at a temperature in the range from 400° C. to 500° C. in the annealing step, and thus the contact resistance between the nitride semiconductor layer and the ohmic electrodes can greatly be reduced in comparison with that resulting from annealing at a high temperature of 500° C. or above.

### Advantageous Effects of Invention

In accordance with the nitride semiconductor devices of the invention and the methods for manufacturing the same, as apparent from above, the nitride semiconductor devices can be provided in which the contact resistance between the GaN-based semiconductor layer and the ohmic electrodes can be reduced.

### BRIEF DESCRIPTION OF DRAWINGS

FIG. 1 is a sectional view of a nitride semiconductor device in accordance with a first embodiment of the invention;

FIG. 2 is a process drawing in section for illustrating a method for manufacturing the nitride semiconductor device;

FIG. 3 is a process drawing in section following FIG. 2;

FIG. 4 is a process drawing in section following FIG. 3;

FIG. 5 is a process drawing in section following FIG. 4;

FIG. 6 is a process drawing in section following FIG. 5;

FIG. 7 is a process drawing in section following FIG. 6;

FIG. 8 is a diagram showing a relation between concentrations of nitrogen in ohmic electrodes and contact resistances; and

FIG. 9 is a diagram showing a relation between annealing temperatures for the ohmic electrodes and the contact resistances.

### DESCRIPTION OF EMBODIMENTS

Hereinbelow, nitride semiconductor devices of the invention and methods for manufacturing the same will be described in detail with reference to embodiments shown in the drawings.

### First Embodiment

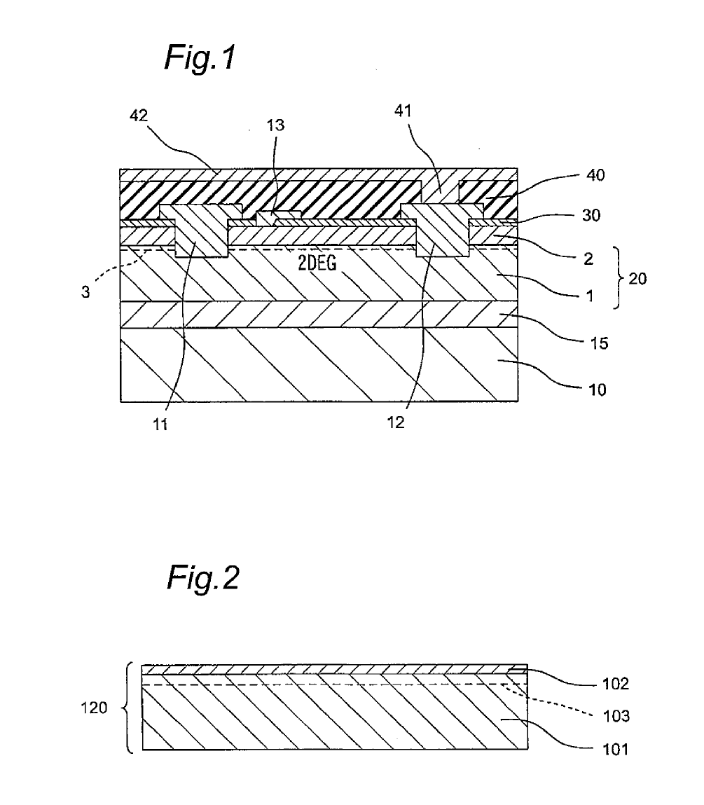

FIG. 1 shows a sectional view of a nitride semiconductor device in accordance with a first embodiment of the invention, and the nitride semiconductor device is a GaN-based HFET (Hetero-junction Field Effect Transistor).

In the semiconductor device, as shown in FIG. 1, an undoped AlGaN buffer layer 15 and a nitride semiconductor layer 20 made of an undoped GaN layer 1 as an example of a first semiconductor layer and an undoped AlGaN layer 2 as an example of a second semiconductor layer are formed on an Si substrate 10. In an interface between the undoped GaN layer 1 and the undoped AlGaN layer 2, 2DEG (two-dimensional electron gas) is produced.

A source electrode 11 and a drain electrode 12 are formed at a distance from each other on the AlGaN layer 2. On the AlGaN layer 2, a gate electrode 13 is formed between the source electrode 11 and the drain electrode 12 and in a position nearer to the source electrode 11. The source electrode 11 and the drain electrode 12 are ohmic electrodes and the gate electrode 13 is a Schottky electrode. The HFET is composed of the source electrode 11, the drain electrode 12, the gate electrode 13, and an active region in the GaN layer 1 and the AlGaN layer 2 where the source electrode 11, the drain electrode 12, and the gate electrode 13 are formed.

The active region refers to a region in the nitride semiconductor layers 20 (the GaN layer 1, the AlGaN layer 2) through which carriers are made to flow between the source electrode 11 and the drain electrode 12 by a voltage applied to the gate electrode 13 placed between the source electrode 11 and the drain electrode 12 on the AlGaN layer 2.

In order to protect the AlGaN layer 2, an insulating film 30 made of SiO₂ is formed on the AlGaN layer 2 except regions where the source electrode 11, the drain electrode 12 and the gate electrode 13 are formed. An interlayer insulating film 40 made of polyimide is formed above the Si substrate 10 having the source electrode 11, the drain electrode 12 and the gate electrode 13 formed above it. In FIG. 1, reference sign 41 denotes a via as a contact part and sign 42 denotes a drain electrode pad. SiN, Al₂O₃ or the like may be used for the insulating film without limitation to SiO₂. In particular, the insulating film preferably has a multilayer film structure made of a non-stoichiometric SiN film and SiO₂, SiN and/or the like for surface protection on a surface of the semiconductor layers, in order that collapse may be suppressed. Insulating materials such as SiO₂ film produced by p-CVD, SOG (Spin On Glass), and BPSG (borophosphosilicate glass) may be used for the interlayer insulating film, without limitation to polyimide.

In the nitride semiconductor device having above configuration, the two-dimensional electron gas (2DEG) is produced in the interface between the GaN layer 1 and the AlGaN layer 2 so as to form a channel layer. The channel layer is controlled by application of a voltage to the gate electrode 13 so as to turn on or turn off the HFET having the source electrode 11, the drain electrode 12 and the gate electrode 13. The HFET is a transistor of normally-on type that is turned off with a depletion layer formed in the GaN layer 1 under the gate electrode 13 when a negative voltage is applied to the gate electrode 13 and that is turned on with the depletion layer eliminated from the GaN layer 1 under the gate electrode 13 when the voltage applied to the gate electrode 13 is zero.

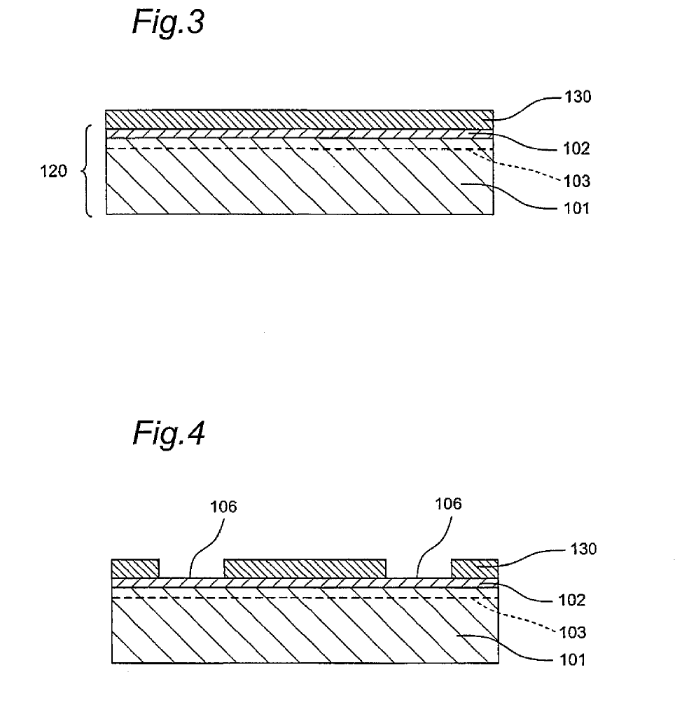

Subsequently, a method for manufacturing the nitride semiconductor device will be described with reference to FIGS. 2 through 7. In FIGS. 3 through 7, for clarification, the Si substrate, the undoped AlGaN buffer layer and the like are omitted, and sizes of the source electrode and the drain electrode, the distance therebetween and the like are modified.

As shown in FIG. 2, initially, the undoped AlGaN buffer layer (not shown), an undoped GaN layer 101, and an undoped AlGaN layer 102 are sequentially formed on the Si substrate (not shown) with use of MOCVD (Metal Organic Chemical Vapor Deposition) technique. Thickness of the undoped GaN layer 101 is, e.g., 1 μm, and thickness of the undoped AlGaN layer 102 is, e.g., 30 μm. The GaN layer 101 and the AlGaN layer 102 form a nitride semiconductor layer. In FIG. 2, reference sign 103 denotes the two-dimensional electron gas (2DEG) formed in the hetero interface between the GaN layer 101 and the AlGaN layer 102.

As shown in FIG. 3, subsequently, an insulating film 130 (e.g., SiO₂) is deposited to 200 nm on the AlGaN layer 102 by plasma CVD (Chemical Vapor Deposition) technique, for instance.

As shown in FIG. 4, subsequently, photoresist is applied onto the insulating film 130, patterning is performed thereon, and parts of the insulating film 130 in which the ohmic electrodes are to be formed are thereafter removed by wet etching, so that recessed parts 106, 106 are formed in the insulating film 130.

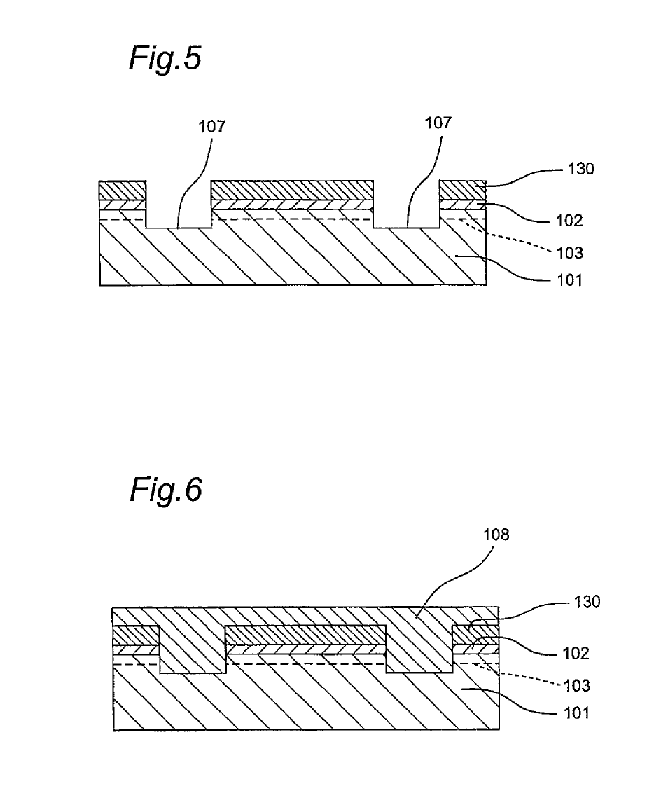

As shown in FIG. 5, subsequently, the AlGaN layer 102 are pierced, portions of upper side of the GaN layer 101 are removed, and recessed parts 107, 107 are formed, by dry etching process in which the insulating film 130 having the recessed parts 106, 106 formed therein is used as a mask. Depth of the recessed parts 107, 107 has only to be as great as or greater than depth from a surface of the AlGaN layer 102 to the 2DEG and is set at 50 nm, for instance. After the dry etching, annealing is performed (at 500 to 850° C., for instance).

As shown in FIG. 6, subsequently, Ti/Al/TiN are laminated by sputtering on the insulating film 130 and the recessed parts 107, 107 (shown in FIG. 5) so as to form a laminated metal film 108 that is to be made into the ohmic electrodes. The TiN layer is a cap layer for protecting the Ti/Al layers in post-process.

At this time, a small quantity (e.g., 5 sccm) of nitrogen is made to flow in a chamber during the formation of the Ti film. Flow rate of the nitrogen is such that formation of nitride of the Ti is prevented.

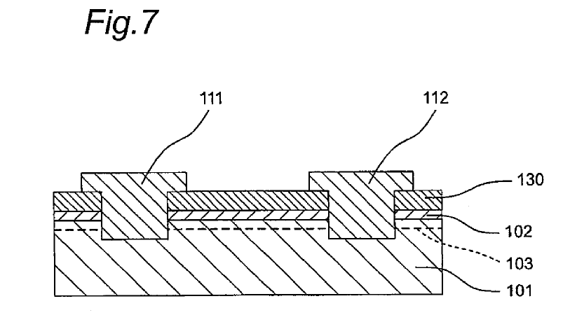

As shown in FIG. 7, subsequently, patterns of the ohmic electrodes 112, 112 are formed with use of conventional photolithography and dry etching processes.

The substrate having the ohmic electrodes 111, 112 formed thereon is annealed for 10 minutes or longer at a temperature in a range from 400° C. to 500° C., for instance, and ohmic contact is thereby obtained between the two-dimensional electron gas (2DEG) and the ohmic electrodes 111, 112. This greatly decreases contact resistance in comparison with that resulting from annealing at a high temperature of 500° C. or above. Additionally, the annealing at the low temperature in the range from 400° C. to 500° C. has no adverse effects on characteristics of the insulating film 130.

The ohmic electrodes 111, 112 form the source electrode and the drain electrode, and the gate electrode made of TiN, WN or the like is formed between the ohmic electrodes 111, 112 in a later process.

In the method for manufacturing the nitride semiconductor device of the first embodiment, nitrogen is made to flow in the chamber during the formation of the Ti film when the laminated metal film 108 (shown in FIG. 6) that is to be made into the ohmic electrodes is formed, and thus concentration of nitrogen in the ohmic electrodes 111, 112 before the annealing for the ohmic contact can be controlled so as to be in a range from 1×10¹⁶ cm⁻³ to 1×10²⁰ cm⁻³. This decreases the contact resistance between the 2DEG in the nitride semiconductor layers and the ohmic electrodes 111, 112 after the annealing.

The concentration of nitrogen in the ohmic electrodes 111, 112 is measured by SIMS (Secondary Ion Mass Spectroscopy) before alloying by the annealing.

The invention is based on various experiments the inventors did on GaN-based HFET as one of nitride semiconductor devices, an accidental finding therein that concentration of nitrogen in ohmic electrodes made of TiAl-based material has an influence on contact resistance, and results of research by the inventors on the influence, whereas specific principles thereof still remain unidentified.

In the nitride semiconductor device having recess structure in which parts of the ohmic electrodes 111, 112 are embedded in the recessed parts 107 extending through the AlGaN layer 102 into the portions of the upper side of the GaN layer 101, the contact resistance between the two-dimensional electron gas (2DEG) in the hetero interface between the GaN layer 101 and the AlGaN layer 102 and the ohmic electrodes 111, 112 can be decreased.

With use of the ohmic electrodes 111, 112 made from the laminated metal film 108 having the Ti layer and the Al layer laminated from a side of the substrate in order of mention, the concentration of nitrogen in the ohmic electrodes can easily be controlled so as to be in the range from 1×10¹⁶ cm⁻³ to 1×10²⁰ cm⁻³ by inclusion of nitrogen in the Ti layer that is initially formed on the AlGaN layer 102.

Though the recessed parts 107 are formed by the removal of the insulating film 130 by the wet etching process and by the subsequent removal of the AlGaN layer 102 and the GaN layer 101 by the dry etching process in the method for manufacturing the nitride semiconductor device of the first embodiment, the recessed parts 107 may be formed by removal of the insulating film 130, the AlGaN layer 102 and the GaN layer 101 by the dry etching process.

Though Ti/Al/TiN are laminated to form the ohmic electrodes in the method for manufacturing the nitride semiconductor device of the first embodiment, the method is not limited thereto, the TiN may be omitted, and Au, Ag, Pt and/or the like may be laminated on laminated Ti/Al.

### Second Embodiment

Subsequently, a method for manufacturing a nitride semiconductor device in accordance with a second embodiment of the invention will be described. The nitride semiconductor device of the second embodiment has the same configuration as the nitride semiconductor device of the first embodiment shown in FIG. 1 has. The method for manufacturing the nitride semiconductor device of the second embodiment includes the same steps as the method for manufacturing the nitride semiconductor device of the first embodiment does, except that nitrogen is made to flow in the chamber before the formation of the Ti film rather than during the formation of the Ti film, and FIGS. 3 through 7 are cited therefor.

Hereinbelow, differences from the method for manufacturing the nitride semiconductor device of the first embodiment will be described.

Though the small quantity of nitrogen is made to flow in the chamber during the formation of the Ti film when Ti/Al/TiN are laminated by the sputtering on the insulating film 130 and the recessed parts 107 so as to form the laminated metal film 108 that is to be made into the ohmic electrodes as shown in FIG. 6 in the first embodiment, the concentration of nitrogen in the ohmic electrodes 111, 112 can be controlled so as to be in the range from 1×10¹⁶ cm⁻³ to 1×10²⁰ cm⁻³ by flow of nitrogen, e.g., at 50 sccm for 5 minutes in the chamber before the formation of the Ti film in the method for manufacturing the nitride semiconductor device of the second embodiment.

The method for manufacturing the nitride semiconductor device of the second embodiment has effects similar to those of the method for manufacturing the nitride semiconductor device of the first embodiment.

In the method for manufacturing the nitride semiconductor device of the second embodiment, nitrogen is made to flow in the chamber before the formation of the Ti film when the laminated metal film 108 that is to be made into the ohmic electrodes is formed by the sputtering, and thus the concentration of nitrogen in the ohmic electrodes 111, 112 can be controlled so as to be in the range from 1×10¹⁶ cm⁻³ to 1×10²⁰ cm⁻³. This decreases the contact resistance between the 2DEG in the nitride semiconductor layers and the ohmic electrodes 111, 112.

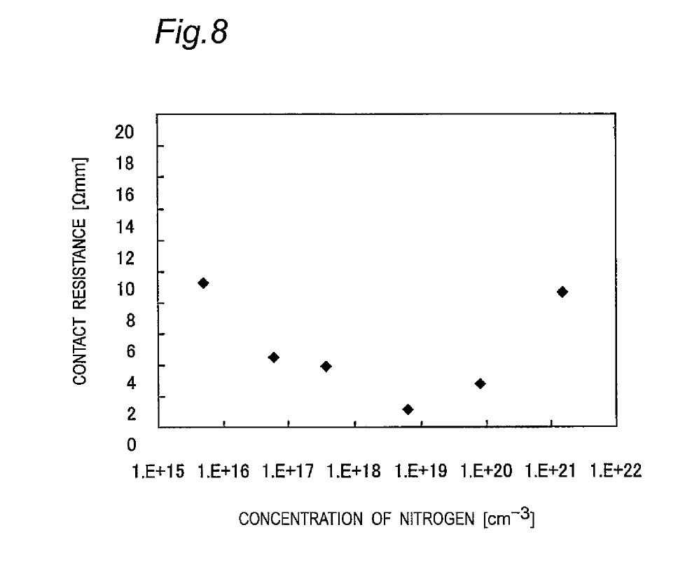

FIG. 8 is a diagram showing a relation between the concentration of nitrogen in the ohmic electrodes and the contact resistance in the nitride semiconductor devices of the first and second embodiments. Four pieces of sample data shown on left side in FIG. 8 were obtained from the nitride semiconductor device manufactured by the manufacturing method (in which nitrogen is made to flow in the chamber before the formation of the Ti film) of the second embodiment, and two pieces of sample data shown on right side in FIG. 8 were obtained from the nitride semiconductor device manufactured by the manufacturing method (in which nitrogen is made to flow in the chamber during the formation of the Ti film) of the first embodiment.

For the concentration of nitrogen (along horizontal axis) in FIG. 8, the concentration of nitrogen in the ohmic electrodes before the annealing was measured by SIMS. The concentration of nitrogen may be measured with use of another measuring method such as AES (Atomic Emission Spectroscopy, Auger Electron Spectroscopy).

For the contact resistance (along vertical axis) in FIG. 8, the contact resistance of the ohmic electrodes after the annealing was measured.

As apparent from FIG. 8, the nitride semiconductor device having the contact resistance of 6 Ωmm or smaller can be produced under a condition that the concentration of nitrogen in the ohmic electrodes is set within the range from 1×10¹⁶ cm⁻³ to 1×10²⁰ cm⁻³. Particularly, a point of inflection with a sharp increase in the contact resistance exists where the concentration of nitrogen in the ohmic electrodes exceeds 1×10²⁰ cm⁻³, and such a point of inflection in the contact resistance characteristic depending on the concentration of nitrogen in the ohmic electrodes has never been known.

Such a nitride semiconductor device having the contact resistances of 6 Ωmm or smaller has commercial values in terms of performance and costs as a product that can be driven by higher current and that is more suitable for operation at high temperature than silicon elements.

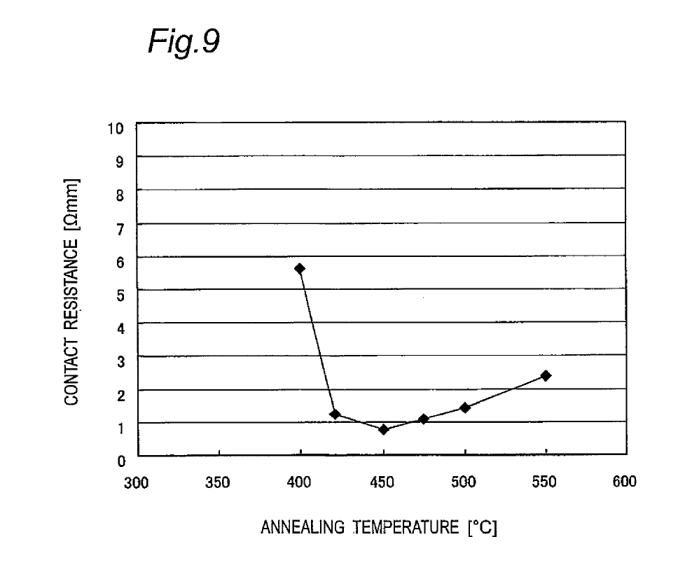

FIG. 9 is a diagram showing a relation between annealing temperature for the ohmic electrodes produced with use of the method for manufacturing the nitride semiconductor device shown in the first embodiment and the contact resistance.

In this operation, sputtering was performed while nitrogen was made to flow at 5 sccm in the chamber during the formation of the Ti film, and then the concentration of nitrogen in the ohmic electrodes before the annealing that was measured by SIMS was 2×10¹⁹ cm⁻³.

It is thus found that the contact resistance between the nitride semiconductor layers and the ohmic electrodes can greatly be reduced by the annealing at a temperature in the range from 400° C. to 500° C.

In the method for manufacturing the nitride semiconductor device, the substrate having the ohmic electrodes formed thereon is heated at a low temperature in the range from 400° C. to 500° C. in a step of the annealing, in contrast to conventional annealing temperatures of 600° C. for n-type GaN and 800° C. for non-doped GaN, and thus the contact resistance between the nitride semiconductor layers and the ohmic electrodes can greatly be reduced in comparison with methods with annealing temperatures lower than 400° C. or higher than 500° C.

Though the nitride semiconductor devices with use of the Si substrates have been described for the first and second embodiments, a sapphire substrate, an SiC substrate or the like may be used without limitation to the Si substrate and the nitride semiconductor layers may be grown on the sapphire substrate, the SiC substrate or the like or the nitride semiconductor layers may be grown on a substrate made of nitride semiconductor, e.g., an AlGaN layer may be grown on a GaN substrate. A buffer layer may be formed between the substrate and the nitride semiconductor layers, and/or a hetero-improvement layer may be formed between the first semiconductor layer and the second semiconductor layer in the nitride semiconductor layers.

Though the HFET having the recess structure in which the ohmic electrodes extend to the GaN layer has been described for the first and second embodiments, the invention may be applied to HFET in which the ohmic electrodes forming the source electrode and the drain electrode are formed on the undoped AlGaN layer without formation of the recesses. Without limitation to the HFET using 2DEG, the same effects can be obtained even from nitride semiconductor devices in accordance with the invention that are field effect transistors with other configurations.

Though the HFET of normally-on type has been described for the first and second embodiments, the invention may be applied to nitride semiconductor devices of normally-off type. The invention may be applied not only to Schottky electrodes but also to field effect transistors having insulated gate structures.

The nitride semiconductor of the nitride semiconductor devices of the invention has only to be a material that can expressed as AlₓIn_{y}Ga_{1-x-y}N (x≧0, y≧0, 0≦x+y≦1).

The specific embodiments of the invention have been described; however, the invention is not limited to the first and second embodiments and can be embodied with modifications in various ways within the scope of the invention.

### REFERENCE SIGNS LIST

1, 101 GaN layer
2, 102 AlGaN layer
3, 103 2DEG
11 source electrode
12 drain electrode
13 gate electrode
15 AlGaN buffer layer
20 nitride semiconductor layer
30, 130 insulating film
40 interlayer insulating film
41 via
42 drain electrode pad
111, 112 ohmic electrode
108 laminated metal film

1. A nitride semiconductor device comprising:
a substrate,
a nitride semiconductor layer formed on the substrate, and
ohmic electrodes formed on the nitride semiconductor layer and made of TiAl-based material, wherein
concentration of nitrogen in the ohmic electrodes made of the TiAl-based material is in a range from 1×10¹⁶ cm⁻³ to 1×10²⁰ cm⁻³.

2. The nitride semiconductor device as claimed in claim 1, wherein
the nitride semiconductor layers comprise a first semiconductor layer and a second semiconductor layer forming a hetero interface in conjunction with the first semiconductor layer, the first and second semiconductor layers laminated on the substrate in order of mention, wherein
two-dimensional electron gas is formed in the hetero interface between the first semiconductor layer and the second semiconductor layer, wherein
recessed parts are formed in portions of upper side of the first semiconductor layer so as to extend through the second semiconductor layer, and wherein at least parts of the ohmic electrodes are embedded in the recessed parts.

3. The nitride semiconductor device as claimed in claim 1, wherein
the ohmic electrodes made of the TiAl-based material are laminated metal films having at least a Ti layer and an Al layer laminated from a side of the substrate in order of mention.

4. A method for manufacturing a nitride semiconductor device, the method comprising steps of:
foaming nitride semiconductor layers on a substrate,
forming a metal film made of TiAl-based material on the nitride semiconductor layers by sputtering,
forming ohmic electrodes by etching the metal film made of the TiAl-based material, and
annealing the substrate having the ohmic electrodes formed thereon, wherein
concentration of nitrogen in the ohmic electrodes is controlled so as to be in a range from 1×10¹⁶ cm⁻³ to 1×10²⁰ cm⁻³ by flow of nitrogen in a chamber during the sputtering of a Ti layer in the metal film made of the TiAl-based material in the step of forming the metal film made of the TiAl-based material.

5. A method for manufacturing a nitride semiconductor device, the method comprising steps of:
forming nitride semiconductor layers on a substrate,
forming a metal film made of TiAl-based material on the nitride semiconductor layers by sputtering,
forming ohmic electrodes by etching the metal film made of the TiAl-based material, and
annealing the substrate having the ohmic electrodes formed thereon, wherein
concentration of nitrogen in the ohmic electrodes is controlled so as to be in a range from 1×10¹⁶ cm⁻³ to 1×10²⁰ cm⁻³ by flow of nitrogen in a chamber before the sputtering of a Ti layer in the metal film made of the TiAl-based material in the step of forming the metal film made of the TiAl-based material.

6. The method for manufacturing the nitride semiconductor device as claimed in claim 4, wherein
the nitride semiconductor layer is formed by laminating a first semiconductor layer and a second semiconductor layer forming a hetero interface in conjunction with the first semiconductor layer, on the substrate in order of mention, and the method further comprising a step of:
forming recessed parts extending through the second semiconductor layer into portions of upper side of the first semiconductor layer, by etching, after forming the nitride semiconductor layers and before forming the metal film made of the TiAl-based material by the sputtering, wherein
the ohmic electrodes having at least parts thereof embedded in the recessed parts are formed by the etching of the metal film made of the TiAl-based material in the step of forming the ohmic electrodes.

7. The method for manufacturing the nitride semiconductor device as claimed in claim 4, wherein
the substrate having the ohmic electrodes formed thereon is heated at a temperature in a range from 400° C. to 500° C. in the annealing step.

8. The method for manufacturing the nitride semiconductor device as claimed in claim 5, wherein
the nitride semiconductor layer is formed by laminating a first semiconductor layer and a second semiconductor layer forming a hetero interface in conjunction with the first semiconductor layer, on the substrate in order of mention, and the method further comprising a step of:
forming recessed parts extending through the second semiconductor layer into portions of upper side of the first semiconductor layer, by etching, after forming the nitride semiconductor layers and before forming the metal film made of the TiAl-based material by the sputtering, wherein
the ohmic electrodes having at least parts thereof embedded in the recessed parts are formed by the etching of the metal film made of the TiAl-based material in the step of forming the ohmic electrodes.

9. The method for manufacturing the nitride semiconductor device as claimed in claim 5, wherein
the substrate having the ohmic electrodes formed thereon is heated at a temperature in a range from 400° C. to 500° C. in the annealing step.
